(19) United States
(12) Patent Application Publication
(10) Pub. No.: US 2007/0075434 A1
(43) Pub. Date: Apr. 5, 2007

(54) Method for producing a PCM memory element and corresponding PCM memory element

(76) Inventors: Ronald Kakoschke, Munchen (DE); Danny Pak-Chum Shum, Poughkeepsie, NY (US)

Correspondence Address: JENKINS, WILSON, TAYLOR & HUNT, P. A., 3100 TOWER BLVD, SUITE 1200, DURHAM, NC, 27707, US

(21) Appl. No.: 11/522,225

(22) Filed: Sep. 15, 2006

Related U.S. Application Data
(63) Continuation of application No. PCT/EP05/03069, filed on Mar. 22, 2005.

(30) Foreign Application Priority Data
Mar. 31, 2004 (DE) 102004015899.1

(51) Int. Cl. H01L 23/48; H01L 23/52; H01L 29/40

(52) U.S. Cl. 257/774

(57) ABSTRACT

The invention relates to a method for producing a PCM memory element and to a corresponding PCM element. The method of production comprises the following steps: providing a first and a second line device (Ma, Mb) underneath an insulating layer (10); providing a hole (5a, 5b) in the insulation layer (10), which partially exposes the first and the second line device (Ma, Mb); providing, as the respective lower electrode, a respective strip-shaped resistor element (20; 20′; 20″) on the wall of the hole (5a, 5b), which electrically contacts the exposed first or second line device (Ma, Mb): providing a filling (30) from an insulating material in the hole (5a, 5b) between the strip-shaped resistor elements (20; 20′; 20″); providing a layer (35) produced from a PCM material in the hole (5a, 5b), which electrically contacts the strip-shaped resistor elements (20; 20′; 20″) on their upper faces; providing a conducting layer (40) above the hole (5a, 5b) and the surrounding surface of the insulating layer (10): forming a sublithographic masking strip (50) on the conducting layer (40) above the hole (5a, 5b) and the surrounding surface of the insulating layer (210) at an angle to the direction of the first and second line device (Ma, Mb): forming segments of the mask strip (50); structuring the conducting layer (40) and the layer (35) produced from the PCM material while using the segments for forming the respective upper electrode from the conducting layer (40) and a PCM area of the layer (35) produced from PCM material lying between the upper and the lower electrode: removing the mask strip (50); and electrically connecting the upper electrode to an additional line device (80).

### RELATED APPLICATIONS

This application is a continuation of PCT International Patent Application No. PCT/EP2005/003069, filed Mar. 22, 2005, which claims priority to German Patent Application No. 102004015899.1, filed Mar. 31, 2004, the disclosures of each of which are incorporated herein by reference in their entitety.

The present invention relates to a method for producing a PCM memory element and to a corresponding PCM memory element.

U.S. Pat. No. 5,166,758 discloses a PCM (phase change memory) memory element in the case of which electrical energy is used for converting a PCM material, typically chalcogenide alloys (e.g. Ge₂Sb₂Te₅), between the crystalline phase (high conductivity, logic “1”) and the amorphous phase (low conductivity, logic “0”).

The conversion from the amorphous phase into the crystalline phase requires a thermal pulse with a temperature which is higher than the glass transition temperature but lower than the melting point, whereas the conversion from the crystalline phase into the amorphous phase requires a thermal pulse with a temperature greater than the melting point followed by rapid cooling.

In the case of the above example of Ge₂Sb₂Te₅, the melting point is 600° C. and the glass transition temperature is 300° C. The crystallization time is typically 50 ns.

A further PCM (phase change memory) memory element having a particular contact structure is disclosed in WO 00/57498 A1, a contact being formed from a sidewall spacer.

PCM memory elements of this type have a whole series of advantageous properties, for example nonvolatility, direct overwritability, nondestructive readability, rapid writing/erasing/reading, long service life (10¹² to 10¹³ read/write cycles), high packing density, low power consumption and good integrability with standard semiconductor processes. In particular, the previously known concepts of SRAM, EEPROM and ROM can be combined in a PCM memory element.

One of the main problems with the known PCM memory elements is the relatively high heat generation during the programming and erasing operations. These problems are suitably remedied by reducing the contact-connected electrode area to increase the current density and consequently lower the energy consumption and the associated heat generation.

IEDM 200136,05, Stefan Lai and Tyler Lowrey, “OUM—A 180 nm Nonvolatile Memory Cell Element Technology For Stand Alone and Embedded Applications” provides a summary of the current state of development of PCM memory elements (also referred to there as “OUM” (Ovonic Unified Memory) memories) in 180 nm technology.

It is therefore an object of the present invention to provide a method for producing a PCM memory element and a corresponding PCM memory element which enable a further reduction of the size and hence of the heat generation during operation.

This problem is solved according to the invention by means of the production method specified in claim 1 and by means of the PCM memory element specified in claim 11.

The idea on which the present invention is based consists in the application of a sublithographic process for reducing the size of the contact area of the PCM memory element. In particular, the invention provides a liner mask technique for the configuration of the top electrode.

Advantageous developments and improvements of the respective subject matter of the invention may be found in the subclaims.

In accordance with one preferred development, the first and second conducting line devices are parallel strips.

In accordance with a further preferred development, two segments of the mask strip are provided, the two segments having an interspace in the center of the hole, so that they each lie only above one strip-type resistance element.

In accordance with a further preferred development, the strip-type resistance elements are provided at the wall of the hole by the following steps of: providing a filling made of the resistance material in the hole; etching back the filling; providing a circumferential spacer (25) in the hole above the etched-back filling; etching the filling using the spacer as a mask; removing the spacer; and photolithographically patterning the etched filling to form the strip-type resistance elements.

In accordance with a further preferred development, the strip-type resistance elements are provided at the wall of the hole by the following steps of: providing a liner layer made of the resistance material in the hole and on the surrounding surface of the insulation material; carrying out a spacer etch for the purpose of removing the liner layer from the bottom of the hole and from the surrounding surface of the insulation material; and photolithographically patterning the etched liner layer to form the strip-type resistance elements.

In accordance with a further preferred development, the strip-type resistance elements and the filling made of the insulation material are etched back in the hole, the layer made of the PCM material being provided as a cover in the hole.

In accordance with a further preferred development, the strip-type resistance elements are etched back by a first depth and the filling made of the insulation material is etched back by a second depth, which is smaller than the first depth, in the hole, the layer made of the PCM material being provided as a circumferential spacer above the strip-type resistance elements in the hole.

In accordance with a further preferred development, the sublithographic mask strips are formed by the following steps of: providing an auxiliary layer on the conductive layer; photolithographically patterning the auxiliary layer to form blocks whose edges define the mask strips; providing a liner layer made of the spacer material; carrying out a spacer etch of the liner layer for the purpose of forming the mask strips; and removing the auxiliary layer.

In accordance with a further preferred development, the top electrodes are electrically connected to the further conducting line device by the following steps of: providing a liner layer and an insulation layer above the structure; providing one or two contact plugs for making contact with the top electrodes in the liner layer and the insulation layer; and providing an interconnect on the insulation layer for making contact with the one or the two contact plugs.

In accordance with a further preferred development, a plurality of pairs of first and second conducting line devices are provided and a plurality of holes are concomitantly provided per pair in the insulation layer, which uncover the first and second conducting line devices in sections in each case.

Exemplary embodiments of the invention are illustrated in the drawings and explained in more detail in the description below.

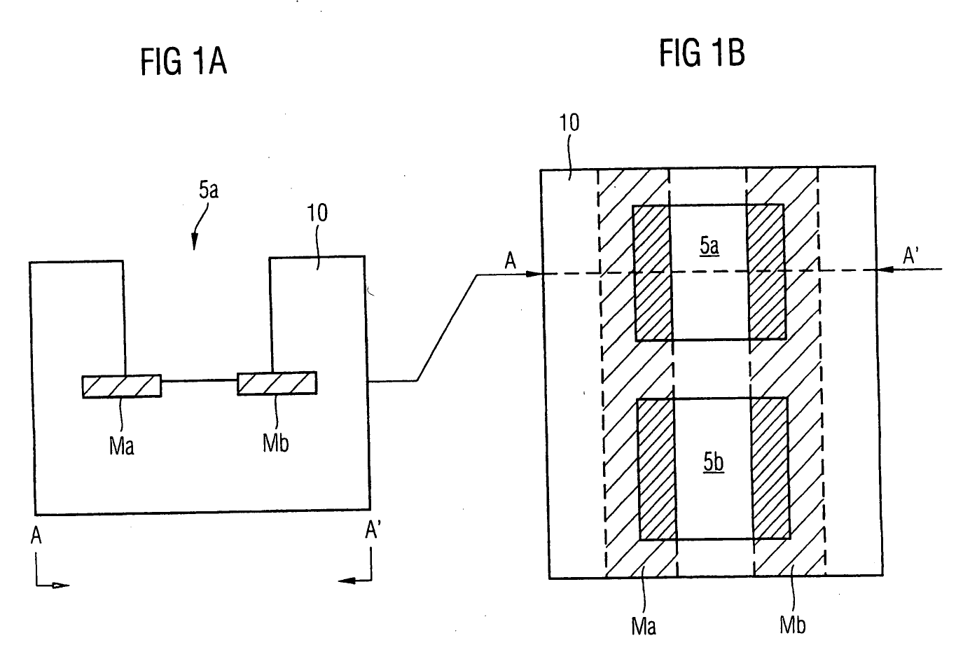

FIGS. 1a, b to 10a, bshow schematic illustrations of successive method stages of a method for producing a PCM memory element as first embodiment of the present invention, to be precise in each case in plan view perspective and cross section perspective;

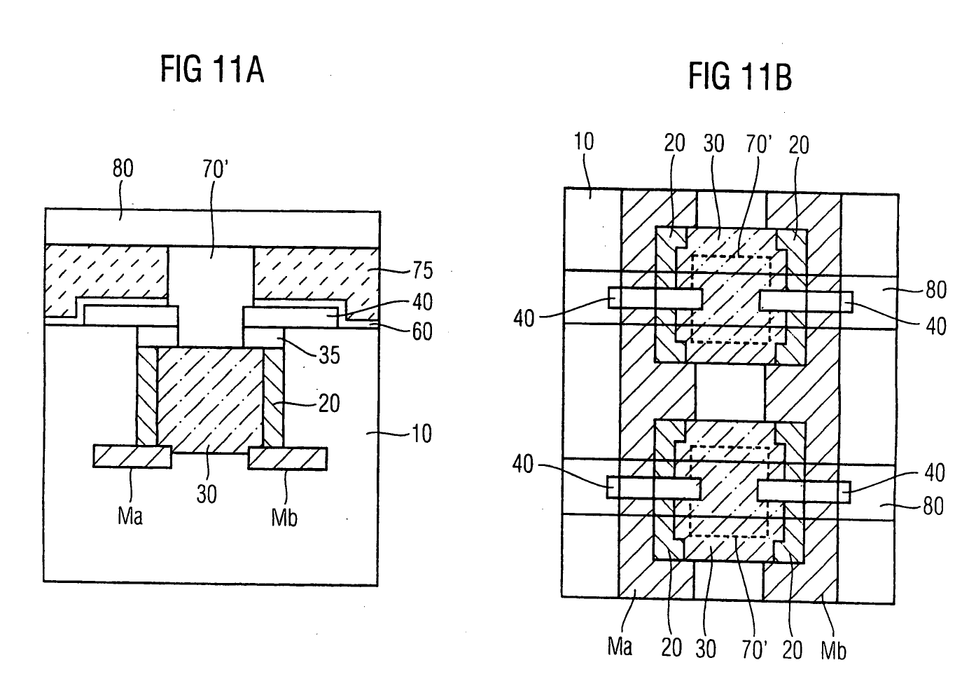

FIGS. 11a, b show schematic illustrations of a method for producing a PCM memory element as second embodiment of the present invention, to be precise one in plan view perspective and one in cross section perspective;

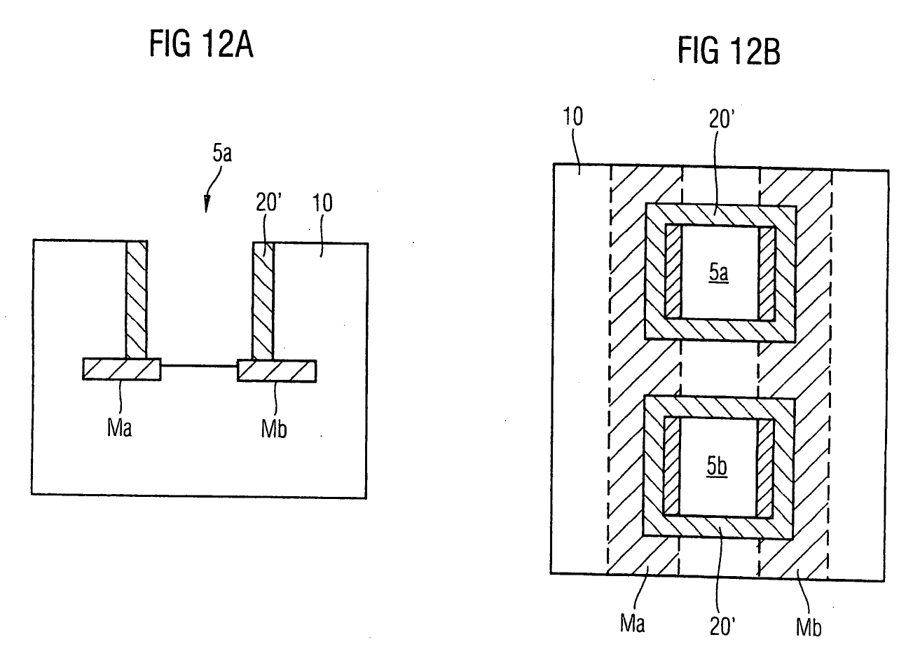

FIGS. 12a, b to 13a, b show schematic illustrations of a method for producing a PCM memory element as third embodiment of the present invention, to be precise in each case in plan view perspective and cross section perspective; and

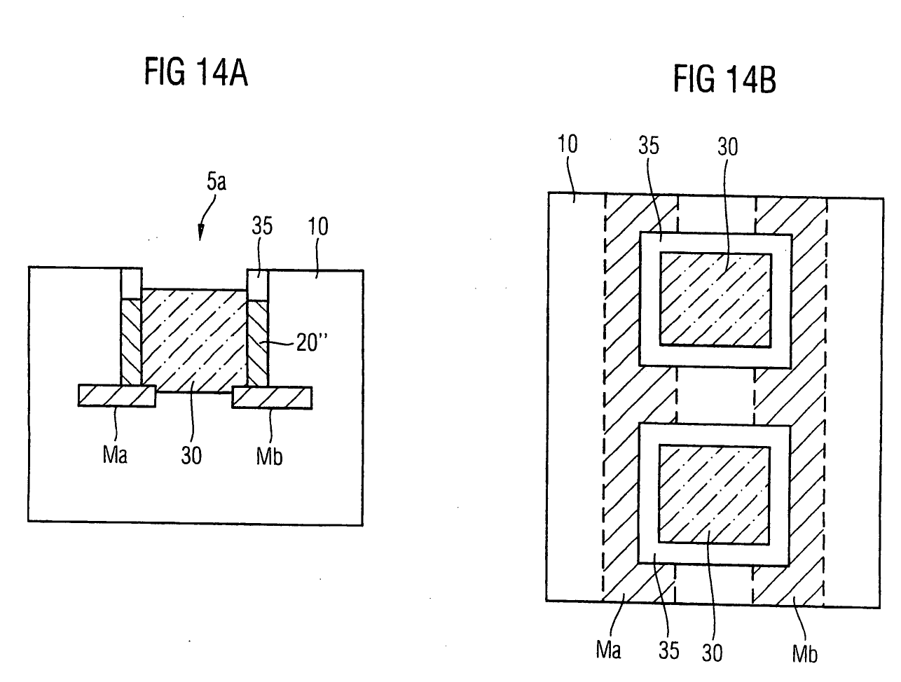

FIGS. 14a, b to 18a, b show schematic illustrations of a method for producing a PCM memory element as fourth embodiment of the present invention, to be precise in each case in plan view perspective and cross section perspective.

In the figures, identical reference symbols designate identical or functionally identical component parts. The cross-sectional plane is always the same and is indicated by the letters A-A′ in FIGS. 1a, b (horizontal central section of the hole 5a).

FIGS. 1a, b to 10a, b show schematic illustrations of successive method stages of a method for producing a PCM memory element as first embodiment of the present invention, to be precise in each case in plan view perspective and cross section perspective.

In FIGS. 1a, reference symbol 10 designates an insulation layer, for example a glass or a low-k material, into which two metallic interconnects Ma and Mb are embedded.

Reference symbols 5a, 5b designate two rectangular holes which are provided alongside one another in the insulation layer 10 and partly uncover the metal interconnects Ma, Mb running parallel in each of the holes 5a, 5b, as illustrated in FIG. 1b. Said holes 5a, 5b may be formed by a customary reactive ion etching step that stops on the metal interconnects Ma, Mb.

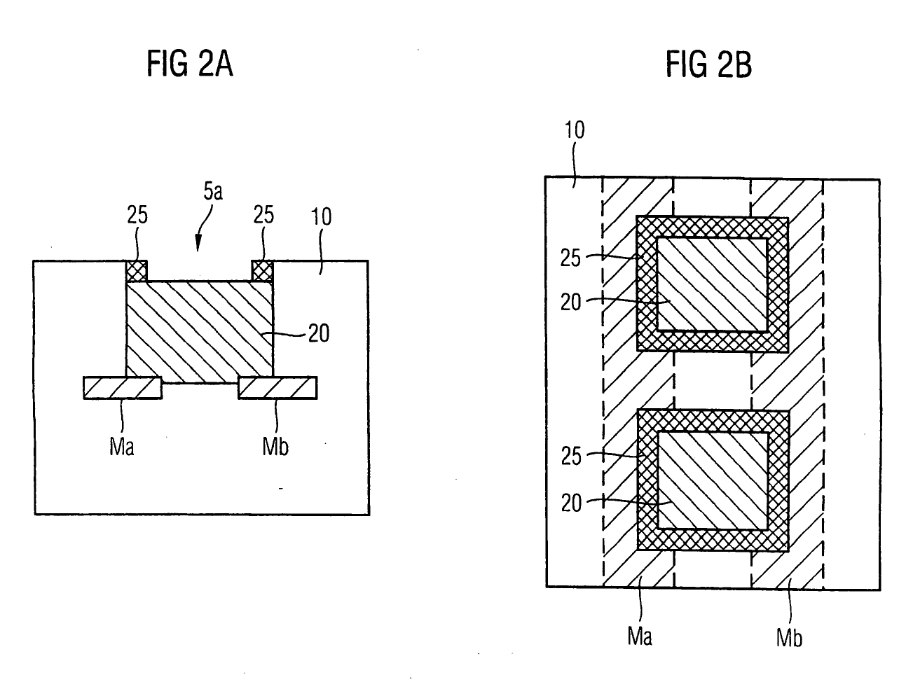

In a subsequent process step, which is illustrated in FIGS. 2a, b, the holes 5a, 5b are filled with a resistance material, for example TiN or WN. The resistance material filling is designated by reference symbol 20. Afterward, the resistance material filling is planarized by means of a CMP step and sunk in the holes 5a, 5b by means of a reactive ion etching process.

In the next process step, a spacer layer made of silicon nitride or TEOS with a thickness of typically 40 nm is deposited above the entire structure and from this spacers 25 having a width of typically 30 nm are formed in the upper region of the holes 5a, 5b by means of a spacer etching process. The spacers run along the entire inner upper circumference of the holes 5a, 5b, as is clearly discernible in FIG. 2b.

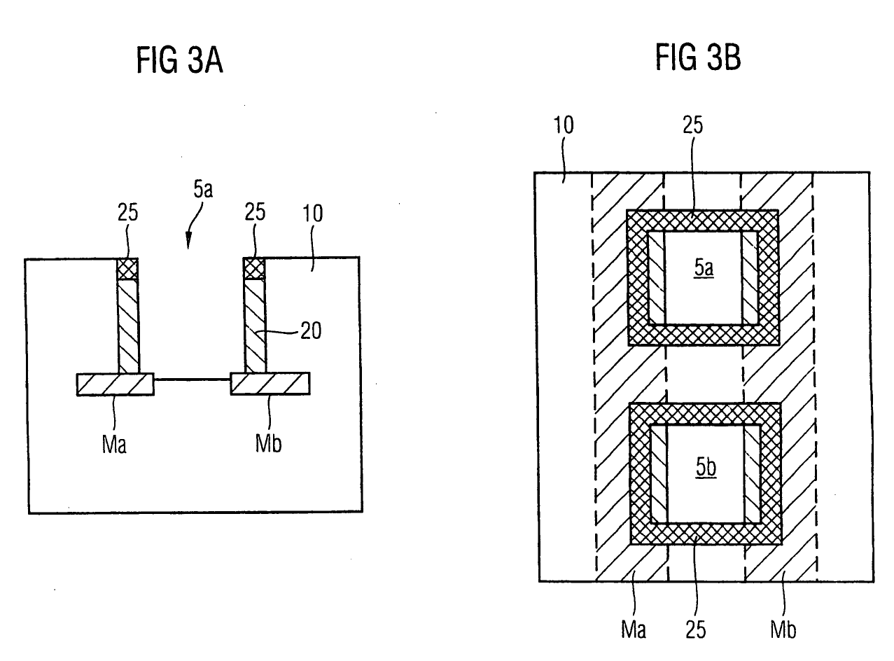

This is followed, referring to FIGS. 3a, b, by a further reactive ion etching step, in which the spacers 25 are used as a mask and in which the resistance material filling 20 is partly removed from the holes 5a, 5b, so that it only remains beneath the spacers 25 in annular strip-type fashion at the walls of the holes 5a, 5b. Said reactive ion etching process likewise stops on the surface of the metal interconnects Ma, Mb and is chosen in such a way that it does not attack the top side of the insulation layer 10.

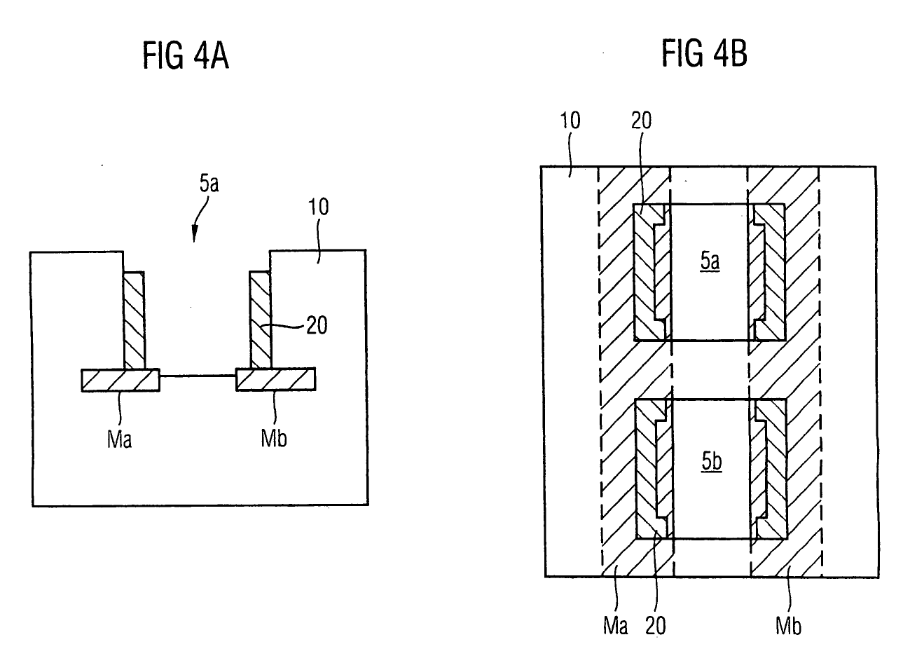

Referring further to FIGS. 4a, b, in the next process step, the spacers 25 are removed selectively relative to the resulting structure by means of an etching step. Afterward, a photoresist mask (not shown) is provided on the top side of the insulation layer 10 and is used to cut through the resistance material filling 20 in the holes 5a, 5b, so that in the holes 5a, 5b U-shaped thin strips remain on the opposite left and right wall halves, as can be discerned in FIG. 4b.

After the resistance material filling 20 has been severed, which is expediently likewise realized by means of a reactive ion etching step, the bottom electrodes of in each case two PCM memory cells in the same hole 5a or 5b, respectively, have been completed.

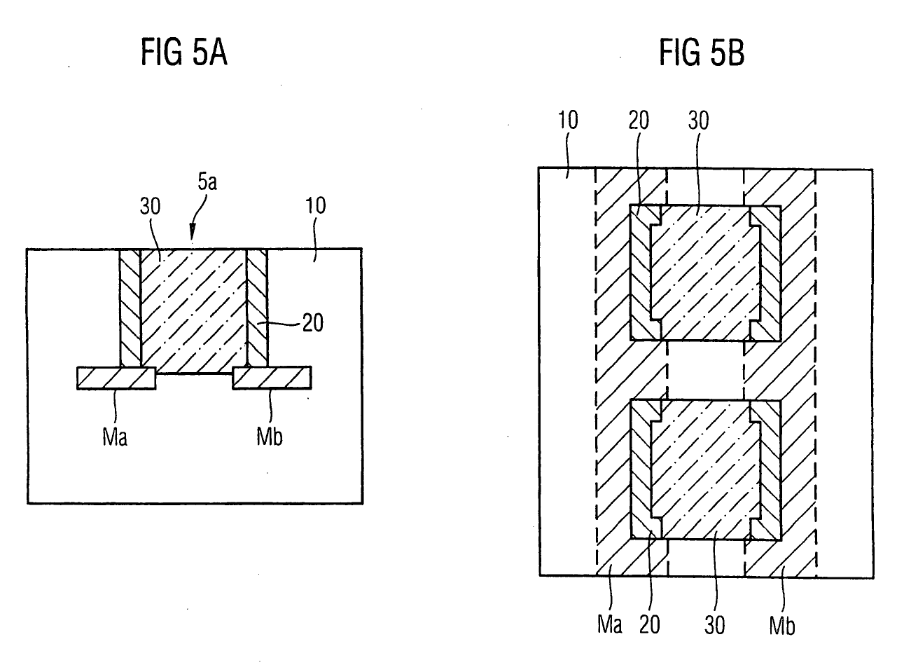

The photoresist mask is then removed from the surface of the insulation layer 10. In the subsequent process step, TEOS insulation material is deposited above the resulting structure and polished back, with the result that an insulation material filling 30 remains in the holes 5a, 5b. During the polishing-back process, which is effected by means of a CMP step, a section of the surface of the insulation layer 10 which, in accordance with FIG. 4a, projects above the top side of the remaining halves of the resistance material filling 20 is likewise removed. Consequently, the top side of the remaining halves of the resistance material filling 20 is ultimately in one plane like the top side of the insulation layer 10 and the insulation material filling 30, as can be seen from FIG. 5a.

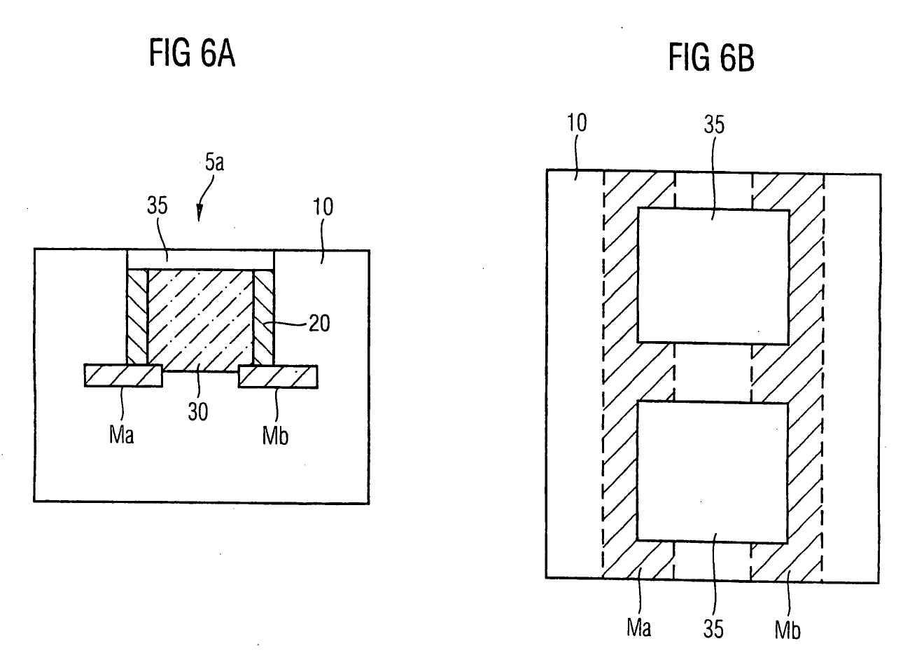

A subsequent process step involves sinking the remaining halves of the resistance material filling 20 in the holes 5a, 5b, and likewise sinking the insulation material filling 30 by the same depth. A PCM material, here Ge₂Sb₂Ti₅, is then deposited, for example by sputtering, above the resulting structure and is polished back in a further CMP step, which leads to the state shown in FIGS. 6a, 6b, according to which the PCM layer 35 equally forms a cover of the holes 5a, 5b.

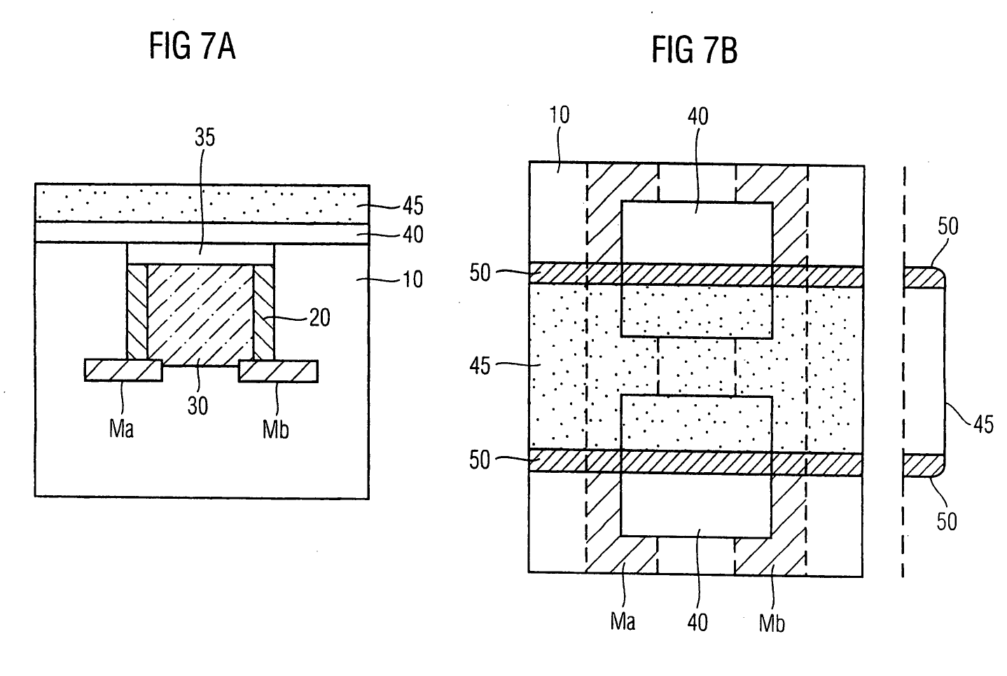

This is followed, referring to FIGS. 7a, 7b, by the deposition of a conductive layer 40 above the entire structure and of an auxiliary layer 45 made of polysilicon above the conductive layer 40.

As illustrated in FIG. 7b, the polysilicon auxiliary layer 45 is then patterned in strip-type fashion by means of a photoresist mask (not shown).

The patterning is effected perpendicular to the direction in which the metal strips Ma, Mb run, and in such a way that approximately half of the holes 5a, 5b is covered. In a further process step, a liner layer made of TEOS is then deposited above the patterned auxiliary layer 45 and subjected to a spacer etch, so that spacer strips run above the holes 5a, 5b essentially perpendicular to the metal interconnects 5a, 5b. This process step has the significant advantage that it creates sublithographic spacer strips 50, the size of which can be made significantly smaller than the lithographic resolution. The thickness of the TEOS layer is usually 40 nm.

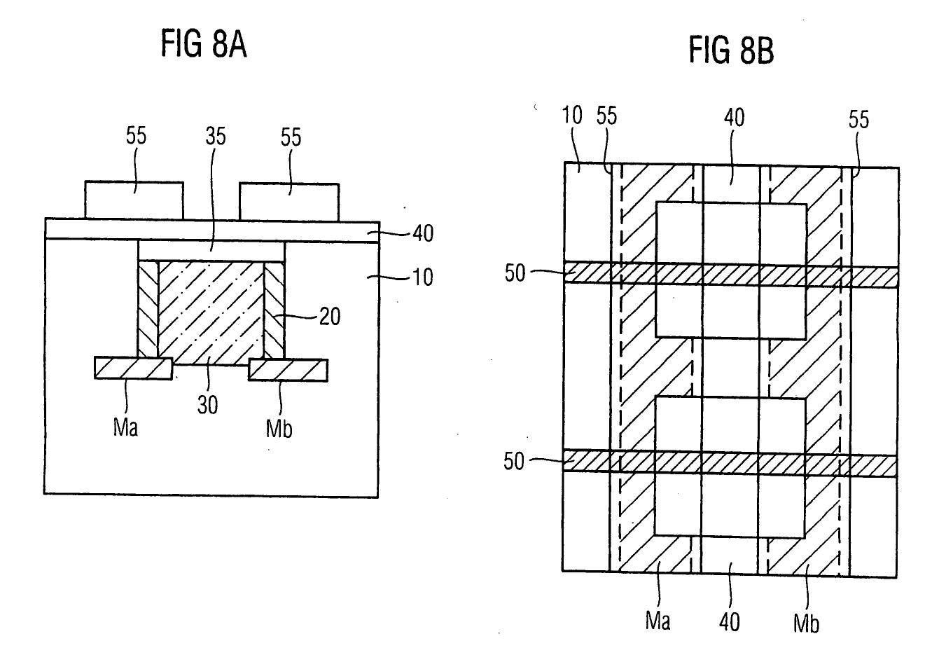

Referring further to FIGS. 8a, b, after the formation of the spacer strips 50, the polysilicon auxiliary layer 45 is removed and a photoresist mask 55 is then formed above the resulting structure, said mask having strips running above the metal interconnects Ma, Mb.

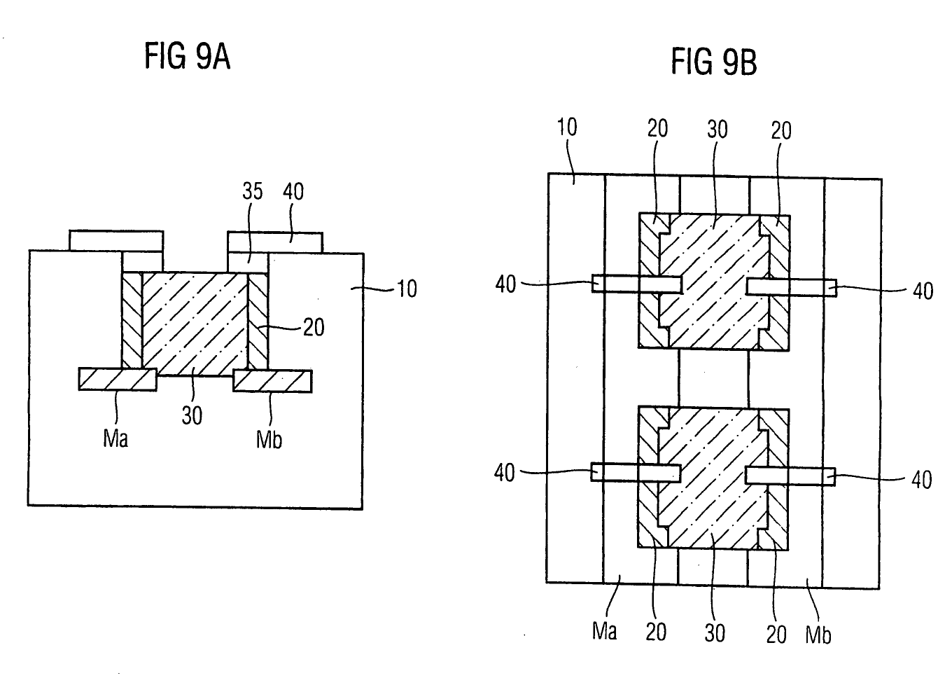

In a subsequent etching process, the spacer strips 50 are then cut open using the photoresist mask 55 and remain only beneath the photoresist mask 55. This is followed, referring to FIGS. 9a, 9b, by removal of the photoresist mask 55 and subsequently by a reactive ion etch of the layer 40 and the underlying PCM layer 35, the remaining segments of the spacer strip 50 serving as an etching mask.

Finally, the segments of the spacer strips 50 are removed selectively in a further etching step, which leads to the structure shown in FIGS. 9a, 9b. This structure has the advantage that only a small volume of the PCM layer 35 through which current later flows during operation is provided between the resistance material filling halves 20 functioning as bottom electrode and the strips 40 functioning as top electrode.

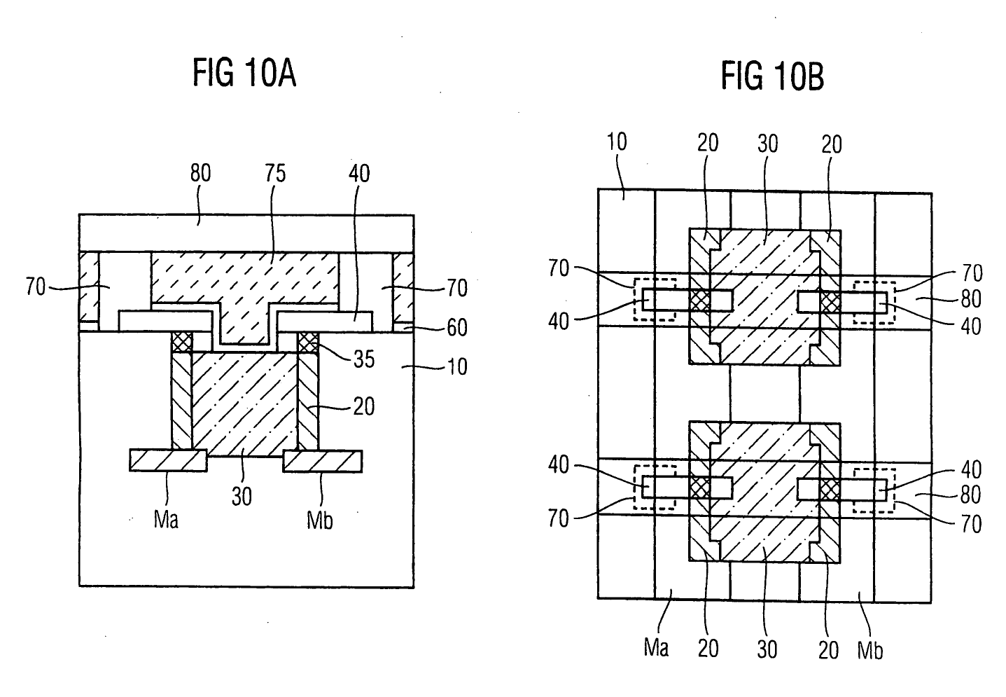

FIGS. 10a, 10b illustrate the concluding process steps for making contact with the strips of the layer 40 which function as top electrode. In a customary manner, a silicon nitride liner layer 60 with a thickness of approximately 30 nm is deposited as an etching stop above the layer and a further insulation layer 75 is subsequently provided above that. Contact plugs 70 are formed in the insulation layer 75 by means of a customary contact hole 10 technique. Finally, metallic connection strips 80 are provided above the resulting structure for the purpose of connecting the contact plugs 70, which leads to the structure shown in FIGS. 10a,10b.

The small volume of the PCM layer 35 which is converted between the phases crystalline/amorphous during operation is specially highlighted by “x” in FIGS. 10a, 10b. By virtue of the small sublithographic configuration of said volume on account of the strips 40 of the top electrodes which are patterned by means of said liner technique, a smaller current suffices to nevertheless obtain a sufficiently high current density which is required for the phase conversion of the PCM material. In this case, the evolution of heat takes place only in a very small volume.

FIGS. 11 a, b show schematic illustrations of a method for producing a PCM memory element as second embodiment of the present invention, to be precise one in plan view perspective and one in cross section perspective.

In the case of the second embodiment shown in FIGS. 11a, 11b, the connection of the strips 40 of the top electrode is realized in a different way. In particular, in that case, after the provision of the liner layer 60 and the insulation layer 75, a contact plug 70′ is formed in the center above the holes 5a, 5b in such a way that contact is made with opposite strips 40 simultaneously. This may be advantageous when arranging the memory elements in a cell array. However, this solution is associated with a higher heat generation since a larger volume of the strips made of the PCM material 35 contributes to the phase change.

FIGS. 12a, b to 13a, b show schematic illustrations of a method for producing a PCM memory element as third embodiment of the present invention, to be precise in each case in plan view perspective and cross section perspective.

In the case of the third embodiment, the halves of the resistance material filling 20 which serve as bottom electrodes are produced in a different way. In particular, this embodiment proceeds from the state in accordance with FIGS. 1a, b, after which a resistance material filling 20 is not provided, rather a liner layer 20′ made of the resistance material is deposited by means of an ALD or CVD method. Said liner layer is subsequently patterned by means of a selective spacer etch in such a way that it only remains at the walls of the holes 5a, 5b, which leads to the process state shown in FIGS. 12a, 12b.

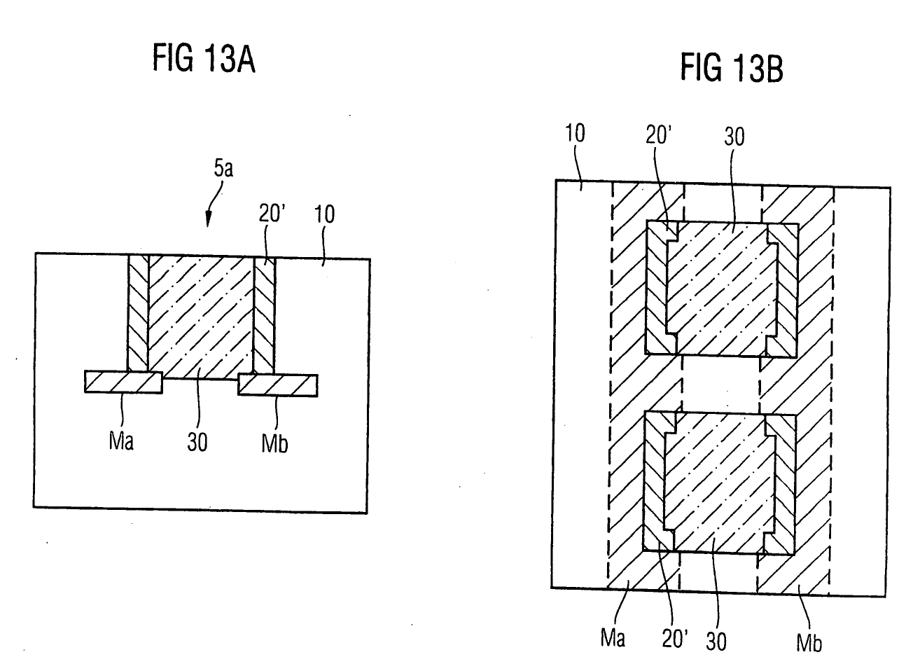

Referring further to FIGS. 13a, 13b, a lithography step corresponding to the lithography step explained in connection with FIGS. 4a, 4b is then carried out in order to cut through the liner layer 20′ made of the resistance material remaining at the walls of the holes 5a, 5b and to form the U-shaped halves already explained at the opposite left and right walls of the holes 5a, 5b. Finally, analogously to FIGS. 5a, 5b, an insulation material filling made of TEOS is deposited and polished back, which leads to the process state shown in FIGS. 13a, 13b. The method is subsequently continued in the manner explained in connection with the first embodiment above in FIGS. 6a, 6b to 10a, 10b.

FIGS. 14a, b to 18a, b show schematic illustrations of a method for producing a PCM memory element as fourth embodiment of the present invention, to be precise in each case in plan view perspective and cross section perspective.

In the case of the fourth embodiment, the initial state is the state shown in FIGS. 4a, 4b after the severing of the resistance material filling 20 at the walls of the holes 5a, 5b.

A subsequent process step involves firstly etching back the resistance material filling 20″ by a first depth and etching back the insulation material filling 30 by a second depth, which is smaller than the first depth. Afterward, a PCM layer 35 is deposited above the resulting structure and subjected to a spacer etch, which leads to the process state shown in FIGS. 14a, 14b.

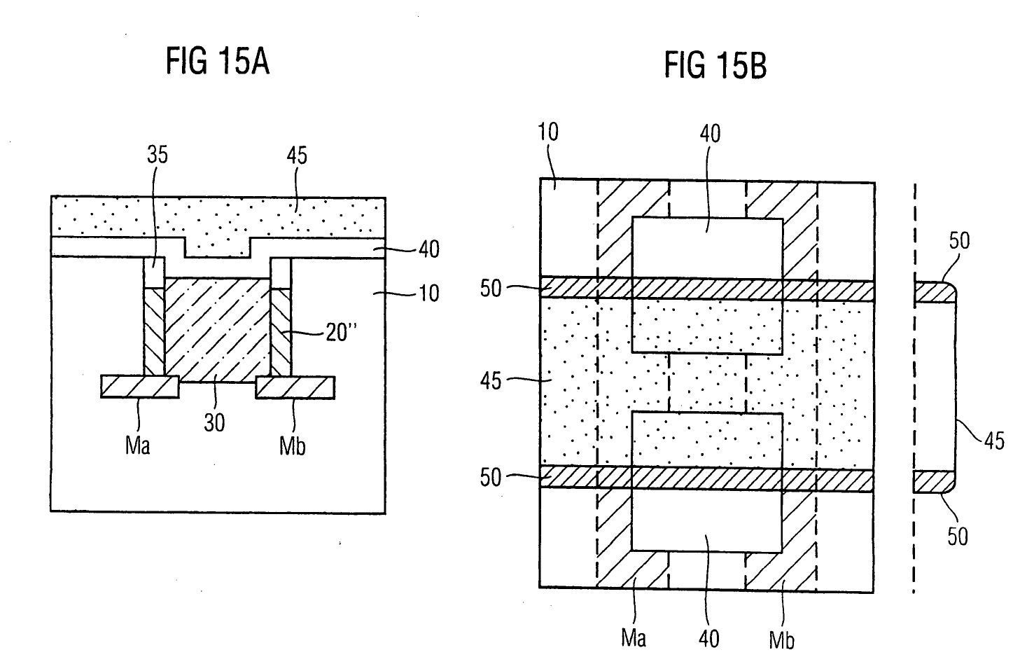

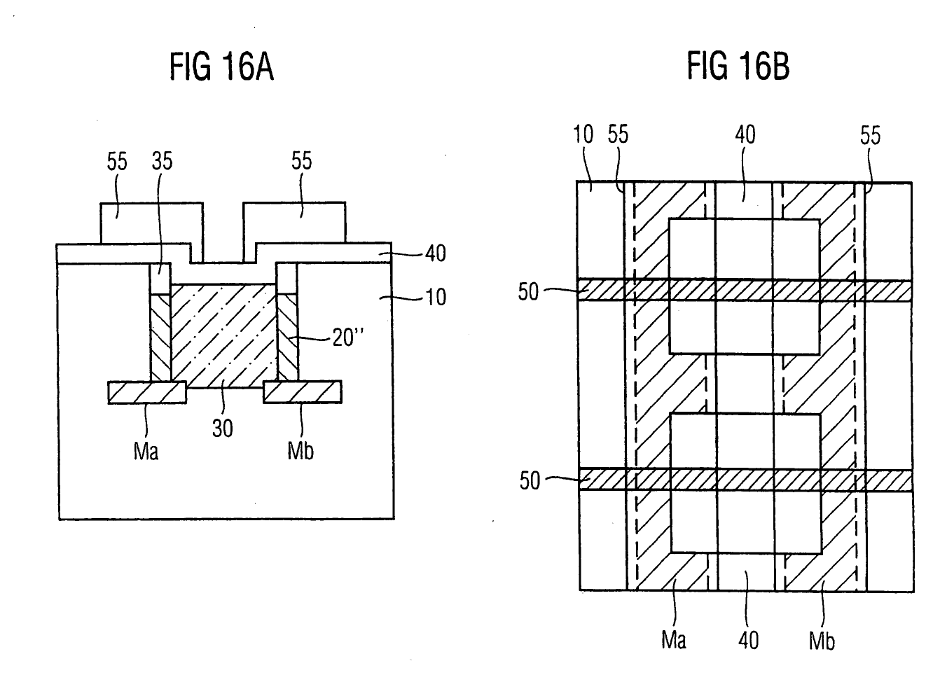

Referring further to FIGS. 15a, 15b, firstly a layer 40 for the top electrodes is deposited above the resulting structure and an auxiliary layer 45 made of polysilicon is deposited above that.

As already explained thoroughly in connection with FIG. 7b, this is followed by patterning of the polysilicon auxiliary layer 45 and the formation of spacer strips 50 in a direction running perpendicular to the metal strips Ma, Mb.

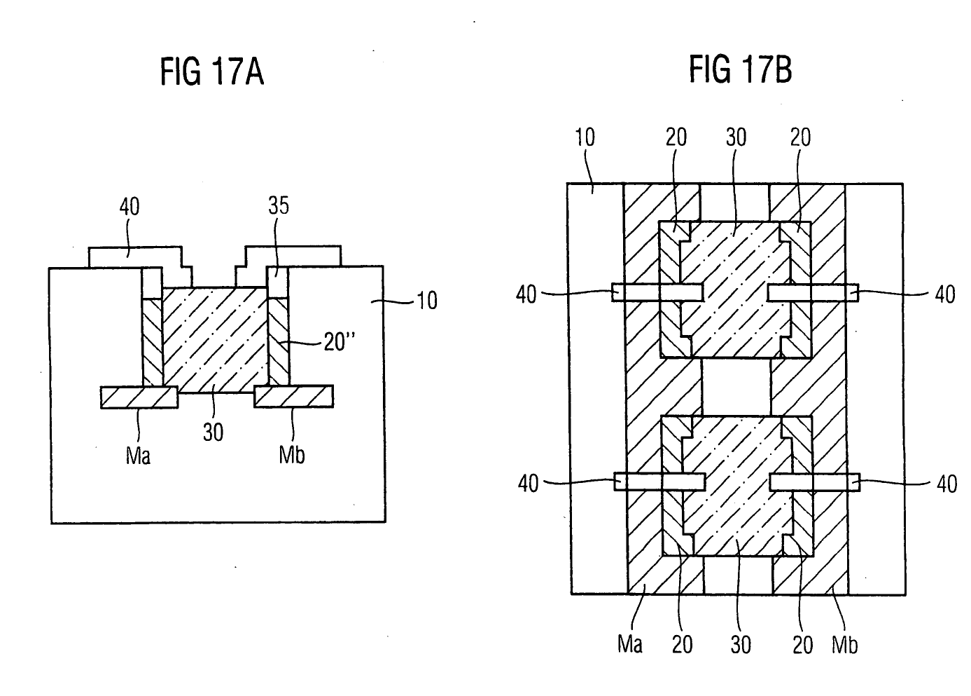

Likewise as already explained, a photoresist mask 55 is then formed on the resulting structure and the spacer strips 50 are thereby subdivided into segments. Removal of the photoresist mask 55 is followed by etching of the layer 40 and the underlying PCM layer 35 using the spacer strip segments as a mask. Removal of the spacer strip segments 50 yields the structure shown in FIGS. 17a, 17b, which structure has sublithographic conductive strips 40 as top electrodes analogously to the first embodiment.

In the case of this fourth embodiment, too, the volume of the PCM layer 35 which contributes to the phase change is very small, so that there is only an extremely low energy requirement for the phase conversion.

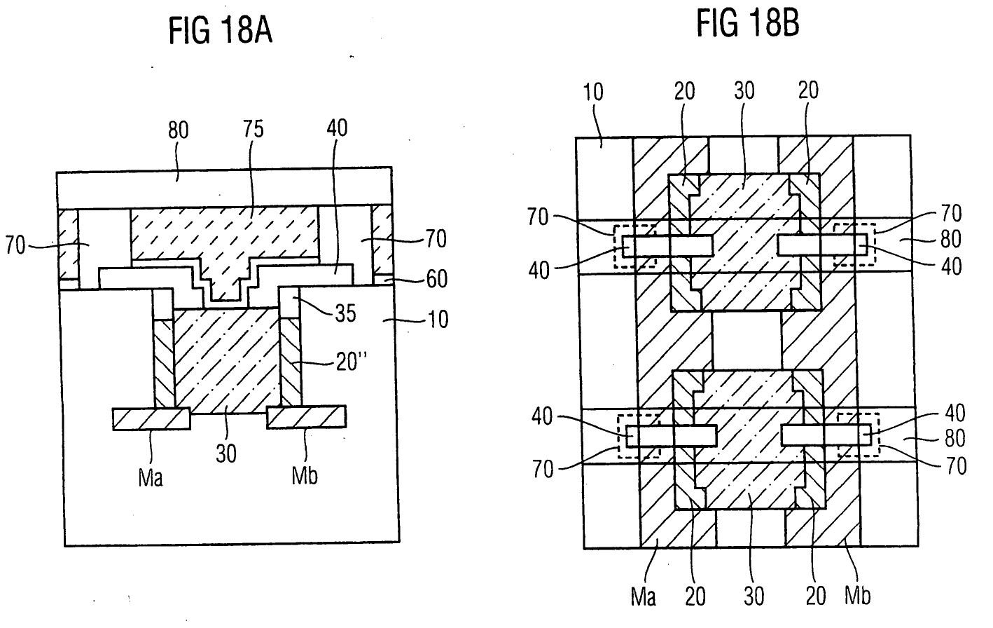

The type of contact-connection of the strips 40 of the top electrodes that is shown in FIGS. 18a, 18b corresponds to the contact-connection explained with reference to FIGS. 10a,10b.

Although the present invention has been described above on the basis of a preferred exemplary embodiment, it is not restricted thereto, but rather can be modified in diverse ways.

In particular, the selection of the layer materials and filling materials is only by way of example and can be varied in many different ways.

Although the PCM memory element has been provided between two adjacent metal planes in the case of the above embodiments, the present invention is not restricted thereto, and the PCM memory elements according to the invention can generally be arranged between arbitrary conductive layers, for example between the substrate and an overlying metal plane.

Moreover, the conducting line devices may be embodied not only as interconnects but e.g. also as diffusion zones or the like.

List of Reference Symbols

10 Insulation layer
Ma, Mb Metal interconnects
5a, 5b Holes
20 Resistance material filling
20′, 20″ Resistance material liner layer
25 Spacer
30 Insulation material filling
35 PCM layer
40 Layer
45 Auxiliary layer
50 Spacer strip
60 Liner layer
70, 70′ Contact plug
75 Insulation layer
80 Metal strip

1. A method for producing a PCM memory element comprising the steps of:
providing a first and second conducting line device (Ma, Mb) below an insulation layer (10);
providing a hole (5a, 5b) in the insulation layer (10), which hole uncovers the first and second conducting line devices (Ma, Mb) in sections;
providing a respective strip-type resistance element (20; 20′; 20″) at the wall of the hole (5a, 5b), which element makes electrical contact with the uncovered first and respectively second conducting line device (Ma, Mb), as a respective bottom electrode;
providing a filling (30) made of an insulation material in the hole (5a, 5b) between the strip-type resistance elements (20; 20′, 20″);
providing a layer (35) made of a PCM material in the hole (5a, 5b), which layer makes electrical contact with the strip-type resistance elements (20; 20′; 20″) at their top side;
providing a conductive layer (40) above the hole (5a, 5b) and the surrounding surface of the insulation layer (10);
forming a sublithographic mask strip (50) on the conductive layer (40) above the hole (5a, 5b) and the surrounding surface of the insulation layer (10) transversely with respect to the direction of the first and second conducting line devices (Ma, Mb);
forming segments of the mask strip (50);
patterning the conductive layer (40) and the layer (35) made of the PCM material using the segments for the purpose of forming the respective top electrode from the conductive layer (40) and a PCM region from the layer (35) made of the PCM material that lies between the top and bottom electrodes;
removing the mask strips (50); and
electrically connecting the top electrodes to a further conducting line device (80).

2. The method as claimed in claim 1,
characterized
in that the first and second conducting line devices (Ma, Mb) are parallel strips.

3. The method as claimed in claim 1 or 2,
characterized
in that two segments of the mask strip (50) are provided, the two segments having an interspace in the center of the hole (5a), so that they each lie only above one strip-type resistance element (20; 20′; 20″).

4. The method as claimed in claim 1, 2 or 3,
characterized
in that the strip-type resistance elements (20; 20′; 20″) are provided at the wall of the hole (5a, 5b) by the following steps of:
providing a filling (20; 20″) made of the resistance material in the hole (5a, 5b);
etching back the filling (20; 20″);
providing a circumferential spacer (25) in the hole (5a, 5b) above the etched-back filling (20; 20″);
etching the filling (20; 20″) using the spacer (25) as a mask;
removing the spacer (25); and
photolithographically patterning the etched filling (20; 20″) to form the strip-type resistance elements (20; 20′; 20″).

5. The method as claimed in claim 1, 2 or 3,
characterized
in that the strip-type resistance elements (20; 20′; 20″) are provided at the wall of the hole (5a, 5b) by the following steps of:
providing a liner layer (20′) made of the resistance material in the hole (5a, 5b) and on the surrounding surface of the insulation material (10);
carrying out a spacer etch for the purpose of removing the liner layer (20′) from the bottom of the hole (5a, 5b) and from the surrounding surface of the insulation material (10); and
photolithographically patterning the etched liner layer (20′) to form the strip-type resistance elements (20; 20′; 20″).

6. The method as claimed in one of the preceding claims,
characterized
in that the strip-type resistance elements (20; 20′) and the filling (30) made of the insulation material are etched back in the hole (5a, 5b) and the layer (35) made of the PCM material is provided as a cover in the hole (5a, 5b).

7. The method as claimed in one of claims 1 to 5,
characterized
in that the strip-type resistance elements (20″) are etched back by a first depth and the filling (30) made of the insulation material is etched back by a second depth, which is smaller than the first depth, in the hole (5a, 5b) and the layer (35) made of the PCM material is provided as a circumferential spacer above the strip-type resistance elements (20″) in the hole (5a, 5b).

8. The method as claimed in one of the preceding claims,
characterized
in that the sublithographic mask strips (50) are formed by the following steps of:
providing an auxiliary layer (45) on the conductive layer (40);
photolithographically patterning the auxiliary layer (45) to form blocks whose edges define the mask strips (50);
providing a liner layer (50) made of the spacer material;
carrying out a spacer etch of the liner layer (50) for the purpose of forming the mask strips (50); and
removing the auxiliary layer (45).

9. The method as claimed in one of the preceding claims,
characterized
in that the top electrodes are electrically connected to the further conducting line device (80) by the following steps of:
providing a liner layer (60) and an insulation layer (75) above the structure;
providing one or two contact plugs (70; 70′) for making contact with the top electrodes in the liner layer (60) and the insulation layer (75); and
providing an interconnect (80) on the insulation layer (75) for making contact with the one or the two contact plugs (70; 70′).

10. The method as claimed in one of the preceding claims 1 to 9,
characterized
in that a plurality of pairs of first and second conducting line devices (Ma, Mb) are provided and a plurality of holes (5a, 5b) are concomitantly provided per pair in the insulation layer (10), which uncover the first and second conducting line devices (Ma, Mb) in sections in each case.

11. A PCM memory element comprising:
a first and second conducting line device (Ma, Mb) below an insulation layer (10);
a hole (5a, 5b) in the insulation layer (10), which hole uncovers the first and second conducting line devices (Ma, Mb) in sections;
a respective strip-type resistance element (20; 20′; 20″) at the wall of the hole (5a, 5b), which element makes electrical contact with the uncovered first and respectively second conducting line device (Ma, Mb), as a respective bottom electrode;
a filling (30) made of an insulation material in the hole (5a, 5b) between the strip-type resistance elements (20; 20′, 20″);
a sublithographically patterned strip—transversely with respect to the direction of the first and second conducting line devices (Ma, Mb)—made of a conductive layer (40) and an underlying layer (35) made of a PCM material as respective top electrode and a PCM region from the layer (35) made of the PCM material that lies between the top and bottom electrodes.

12. The PCM memory element as claimed in claim 11,
characterized
in that the first and second conducting line devices (Ma, Mb) are parallel strips.

13. The PCM memory element as claimed in claim 11 or 12,
characterized
in that the strip made of a conductive layer (40) and an underlying layer (35) made of a PCM material has two segments, the two segments having an interspace in the center of the hole (5a), so that they are in each case connected only to one strip-type resistance element (20; 20′; 20″).

14. The PCM memory element as claimed in claim 11, 12 or 13,
characterized
in that the strip-type resistance elements (20; 20′; 20″) are arranged perpendicular to the strips made of the conductive layer (40) and the underlying layer (35) made of the PCM material.
